(19) United States
(12) Patent Application Publication
(10) Pub. No.: US 2016/0203994 A1
(43) Pub. Date: Jul. 14, 2016

(54) POLISHING COMPOSITION

(71) Applicant: FUJIMI INCORPORATED, Kiyosu-shi (JP)

(72) Inventors: Shuugo YOKOTA, Kiyosu-shi (JP); Yasuyuki YAMATO, Kiyosu-shi (JP); Satoru YARITA, Kiyosu-shi (JP); Tomohiko AKATSUKA, Kiyosu-shi (JP)

(73) Assignee: FUJIMI INCORPORATED, Kiyosu-shi (JP)

(21) Appl. No.: 15/076,869

(22) Filed: Mar. 22, 2016

Related U.S. Application Data
(62) Division of application No. 14/359,258, filed on May 19, 2014.

(30) Foreign Application Priority Data
Nov. 25, 2011 (JP) 2011-258345

(51) Int. Cl. H01L 21/306; C09G 1/04

(52) U.S. Cl. CPC H01L 21/30625; C09G 1/04; H01L 21/30612

(57) ABSTRACT

A polishing composition of the present invention is to be used for polishing an object including a portion containing a group III-V compound material. The polishing composition contains an oxidizing agent and an anticorrosive agent. The anticorrosive agent is preferably a nitrogen-containing organic compound, such as 1H-1,2,4-triazole and benzotriazole, or an organic compound having a carboxyl group, for example, dicarboxylic acid, such as malonic acid, succinic acid, glutaric acid, adipic acid, pimelic acid, maleic acid, phthalic acid, malic acid, and tartaric acid, or tricarboxylic acid, such as citric acid.

### CROSS-REFERENCE TO RELATED APPLICATIONS

The present application is a divisional application of U.S. application Ser. No. 14/359,258, filed May 19, 2014, which is a National Stage of International Application No. PCT/JP2012/080221, filed Nov. 21, 2012, which claims the benefit of priority from Japanese Patent Application No. 2011-258345, filed Nov. 25, 2011; the entire contents of all of which are incorporated herein by reference.

### TECHNICAL FIELD

The present invention relates to a polishing composition to be used for polishing an object including a portion containing a group III-V compound material. The present invention also relates to a polishing method and substrate production method using the polishing composition.

### BACKGROUND ART

Group III-V compound materials, such as gallium arsenide (GaAs), have higher electron and hole mobility than that of silicon and an excellent carrier transport property, and are expected as next-generation semiconductor channel materials. A group III-V compound channel can be formed by polishing an object including a portion containing a group III-V compound material (hereinafter, also referred to as a group III-V compound material portion) and a portion containing a silicon material (hereinafter, also referred to as a silicon material portion). At this time, in addition to the polishing of the group III-V compound material portion at a high polishing rate, the prevention of the occurrence of a level difference caused by etching is required on a polished surface of the object. However, a polishing composition conventionally used for polishing a group III-V compound semiconductor substrate and described in, for example, Patent Documents 1 or 2 is specifically developed for the group III-V compound semiconductor substrate. Therefore, when the polishing composition is used for polishing an object including a group III-V compound material portion and a portion containing a material other than group III-V compounds, the group III-V compound material portion is excessively polished and etched, which makes it difficult to prevent the occurrence of a level difference caused by etching on a polished surface.

### PRIOR ART DOCUMENTS

Patent Document 1: Japanese Laid-Open Patent Publication No. 63-150155

Patent Document 2: Japanese Laid-Open Patent Publication No. 2004-327614

### SUMMARY OF THE INVENTION

### Problems that the Invention is to Solve

Accordingly, it is an objective of the present invention to provide a polishing composition capable of suppressing the occurrence of a level difference caused by etching on a polished surface of an object including a group III-V compound material portion, and a polishing method and substrate production method using the polishing composition.

### Means for Solving the Problems

In order to achieve the above-mentioned objective and in accordance with a first aspect of the present invention, provided is a polishing composition to be used for polishing an object including a group III-V compound material portion. The polishing composition contains an oxidizing agent and an anticorrosive agent.

The anticorrosive agent is preferably a nitrogen-containing organic compound or an organic compound having a carboxyl group.

In accordance with a second aspect of the present invention, provided is a method for polishing an object including a group III-V compound material portion with the polishing composition of the first aspect.

In accordance with a third aspect of the present invention, provided is a method for producing a substrate by polishing an object including a group III-V compound material portion with the polishing composition of the first aspect.

### EFFECTS OF THE INVENTION

The present invention succeeds in providing a polishing composition capable of suppressing the occurrence of a level difference caused by etching on a polished surface of an object including a group III-V compound material portion, and a polishing method and substrate production method using the polishing composition.

### MODES FOR CARRYING OUT THE INVENTION

One embodiment of the present invention will be described below.

A polishing composition of the present embodiment is prepared by mixing an oxidizing agent and an anticorrosive agent with water. Therefore, the polishing composition contains an oxidizing agent and an anticorrosive agent.

The polishing composition is used for polishing an object including a group III-V compound material portion, and specifically for polishing the object to produce a substrate. The object to be polished may further include a silicon material portion. Examples of the group III-V compound material include gallium phosphide (GaP), indium phosphide (InP), gallium arsenide (GaAs), indium arsenide (InAs), and indium antimonide (InSb). Examples of the silicon material include polysilicon, silicon oxide, and silicon nitride.

### (Oxidizing Agent)

Although the type of the oxidizing agent contained in the polishing composition is not particularly limited, the oxidizing agent preferably has a standard electrode potential of 0.3 V or more. When an oxidizing agent having a standard electrode potential of 0.3 V or more is used, the polishing rate of the group III-V compound material portion and the silicon material portion with the polishing composition is advantageously enhanced as compared with when an oxidizing agent having a standard electrode potential of less than 0.3 V is used. Specific examples of an oxidizing agent having a standard electrode potential of 0.3 V or more include hydrogen peroxide, sodium peroxide, barium peroxide, an organic oxidizing agent, ozone water, a silver (II) salt, an iron (III) salt, permanganic acid, chromic acid, dichromic acid, peroxodisulfuric acid, peroxophosphoric acid, peroxosulfuric acid, peroxoboric acid, performic acid, peracetic acid, perbenzoic acid, perphthalic acid, hypochlorous acid, hypobromous acid, hypoiodous acid, chloric acid, chlorous acid, perchloric acid, bromic acid, iodic acid, periodic acid, sulfuric acid, persulfuric acid, citric acid, dichloroisocyanuric acid, and salts thereof. Among them, hydrogen peroxide, ammonium persulfate, and sodium dichloroisocyanurate are preferable since the polishing rate of the group III-V compound material portion and the silicon material portion with the polishing composition is greatly enhanced.

The standard electrode potential is represented by the following formula when all chemical species participating in an oxidation reaction are in a normal state:

E0=−ΔG0/nF=(RT/nF)lnK

where E0 is a standard electrode potential; ΔG0 is standard Gibbs energy change of the oxidation reaction; K is an equilibrium constant thereof; F is a Faraday constant; T is an absolute temperature; and n is the number of electrons participating in the oxidation reaction. Therefore, since the standard electrode potential fluctuates with a temperature, a standard electrode potential at 25° C. is utilized in the present specification. The standard electrode potential of an aqueous solution system is described in, for example, the Handbook of Chemistry (fundamental part) II, revised 4th edition, pp. 464-468 (edited by the Chemical Society of Japan).

The content of the oxidizing agent in the polishing composition is preferably 0.01 mol/L or more, and more preferably 0.1 mol/L or more. As the oxidizing agent content increases, the polishing rate of the group III-V compound material portion with the polishing composition is enhanced.

The content of the oxidizing agent in the polishing composition is also preferably 100 mol/L or less, and more preferably 50 mol/L or less. As the oxidizing agent content decreases, the material cost of the polishing composition can be reduced, and additionally, the burden of treating the polishing composition after use in polishing, that is, the burden of waste liquid treatment can be reduced.

### (Anticorrosive Agent)

Although the type of the anticorrosive agent contained in the polishing composition is not particularly limited, the anticorrosive agent is preferably a nitrogen-containing organic compound or an organic compound having a carboxyl group, i.e., a carboxylic acid. Examples of a nitrogen-containing organic compound include an amine compound and a nitrogen-containing heterocyclic compound. Among them, a nitrogen-containing heterocyclic compound is preferable. Specific examples of a nitrogen-containing heterocyclic compound include pyrroles, pyrazoles, imidazoles, triazoles, tetrazoles, pyridines, pyrazines, pyridazines, pyrindines, indolizines, indoles, isoindoles, indazoles, purines, quinolizines, quinolines, isoquinolines, naphthyridines, phthalazines, quinoxalines, quinazolines, cinnolines, buterizines, thiazoles, isothiazoles, oxazoles, isoxazoles, and furazans. Examples of pyrazoles include 1H-pyrazole, 4-nitro-3-pyrazolecarboxylic acid, 3,5-pyrazolecarboxylic acid, 3-amino-5-phenylpyrazole, 5-amino-3-phenylpyrazole, 3,4,5-tribromopyrazole, 3-aminopyrazole, 3,5-dimethylpyrazole, 3,5-dimethyl-1-hydroxymethylpyrazole, 3-methylpyrazole, 1-methylpyrazole, 3-amino-5-methylpyrazole, 4-amino-pyrazolo[3,4-d]pyrimidine, allopurinol, 4-chloro-1H-pyrazolo[3,4-D]pyrimidine, 3,4-dihydroxy-6-methylpyrazolo(3,4-B)-pyridine, and 6-methyl-1H-pyrazolo[3,4-b]pyridine-3-amine. Examples of imidazoles include imidazole, 1-methylimidazole, 2-methylimidazole, 4-methylimidazole, 1,2-dimethylpyrazole, 2-ethyl-4-methylimidazole, 2-isopropylimidazole, benzimidazole, 5,6-dimethylbenzimidazole, 2-aminobenzimidazole, 2-chlorobenzimidazole, 2-methylbenzimidazole, 2-(1-hydroxyethyl) benzimidazole, 2-hydroxybenzimidazole, 2-phenylbenzimidazole, 2,5-dimethylbenzimidazole, 5-methylbenzimidazole, 5-nitrobenzimidazole, and 1H-purine. Examples of triazoles include 1,2,3-triazole, 1,2,4-triazole, 1-methyl-1,2,4-triazole, methyl-1H-1,2,4-triazole-3-carboxylate, 1,2,4-triazole-3-carboxylic acid, 1,2,4-triazole-3-methyl carboxylate, 1H-1,2,4-triazole-3-thiol, 3,5-diamino-1H-1,2,4-triazole, 3-amino-1,2,4-triazole-5-thiol, 3-amino-1H-1,2,4-triazole, 3-amino-5-benzyl-4H-1,2,4-triazole, 3-amino-5-methyl-4H-1,2,4-triazole, 3-nitro-1,2,4-triazole, 3-bromo-5-nitro-1,2,4-triazole, 4-(1,2,4-triazole-1-yl)phenol, 4-amino-1,2,4-triazole, 4-amino-3,5-dipropyl-4H-1,2,4-triazole, 4-amino-3,5-dimethyl-4H-1,2,4-triazole, 4-amino-3,5-dipeptyl-4H-1,2,4-triazole, 5-methyl-1,2,4-triazole-3,4-diamine, 1H-benzotriazole, 1-hydroxybenzotriazole, 1-aminobenzotriazole, 1-carboxybenzotriazole, 5-chloro-1H-benzotriazole, 5-nitro-1H-benzotriazole, 5-carboxy-1H-benzotriazole, 5-methyl-1H-benzotriazole, 5,6-dimethyl-1H-benzotriazole, 1-(1′,2′-dicarboxyethyl)benzotriazole, 1-[N,N-bis(hydroxyethyl)aminomethyl]benzotriazole, and 1-[N,N-bis(hydroxyethyl)aminomethyl]-5-methylbenzotriazole. Examples of tetrazoles include 1H-tetrazole, 5-methyltetrazole, 5-aminotetrazole, and 5-phenyltetrazole. Examples of indazoles include 1H-indazole, 5-amino-1H-indazole, 5-nitro-1H-indazole, 5-hydroxy-1H-indazole, 6-amino-1H-indazole, 6-nitro-1H-indazole, 6-hydroxy-1H-indazole, and 3-carboxy-5-methyl-1H-indazole. Examples of indoles include 1H-indole, 1-methyl-1H-indole, 2-methyl-1H-indole, 3-methyl-1H-indole, 4-methyl-1H-indole, 5-methyl-1H-indole, 6-methyl-1H-indole, 7-methyl-1H-indole, 4-amino-1H-indole, 5-amino-1H-indole, 6-amino-1H-indole, 7-amino-1H-indole, 4-hydroxy-1H-indole, 5-hydroxy-1H-indole, 6-hydroxy-1H-indole, 7-hydroxy-1H-indole, 4-methoxy-1H-indole, 5-methoxy-1H-indole, 6-methoxy-1H-indole, 7-methoxy-1H-indole, 4-chloro-1H-indole, 5-chloro-1H-indole, 6-chloro-1H-indole, 7-chloro-1H-indole, 4-carboxy-1H-indole, 5-carboxy-1H-indole, 6-carboxy-1H-indole, 7-carboxy-1H-indole, 4-nitro-1H-indole, 5-nitro-1H-indole, 6-nitro-1H-indole, 7-nitro-1H-indole, 4-nitrile-1H-indole, 5-nitrile-1H-indole, 6-nitrile-1H-indole, 7-nitrile-1H-indole, 2,5-dimethyl-1H-indole, 1,2-dimethyl-1H-indole, 1,3-dimethyl-1H-indole, 2,3-dimethyl-1H-indole, 5-amino-2,3-dimethyl-1H-indole, 7-ethyl-1H-indole, 5-(aminomethyl)indole, 2-methyl-5-amino-1H-indole, 3-hydroxymethyl-1H-indole, 6-isopropyl-1H-indole, and 5-chloro-2-methyl-1H-indole. Among them, 1H-1,2,4-triazole and benzotriazole are preferable.

Specific examples of an organic compound having a carboxyl group include formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, lactic acid, diglycolic acid, 2-furancarboxylic acid, 2,5-furandicarboxylic acid, 3-furancarboxylic acid, 2-tetrahydrofurancarboxylic acid, methoxyacetic acid, methoxyphenylacetic acid, polyoxy alkyl ether acetic acid, phenoxyacetic acid, caprylic acid, pelargonic acid, capric acid, lauric acid, myristic acid, pentadecylic acid, palmitic acid, margaric acid, stearic acid, arachic acid, behenic acid, lignoceric acid, cerotic acid, montanic acid, melissic acid, eicosapentaenoic acid, oleic acid, linolic acid, and linolenic acid. Among them, dicarboxylic acid, such as malonic acid, succinic acid, glutaric acid, adipic acid, pimelic acid, maleic acid, phthalic acid, malic acid, and tartaric acid, and tricarboxylic acid, such as citric acid, are preferable.

The anticorrosive agent forms a complex with the group III-V compound material portion to form a protective film on the surface of the group III-V compound material portion of the object to be polished. The etching of the group III-V compound material portion during polishing is suppressed by the protective film, and thereby preventing the occurrence of a level difference, such as dishing and erosion, on a polished surface of the object.

The content of the anticorrosive agent in the polishing composition is preferably 0.001 mol/L or more, and more preferably 0.01 mol/L or more. As the anticorrosive agent content increases, the occurrence of a level difference caused by etching is further suppressed.

The content of the anticorrosive agent in the polishing composition is also preferably 1 mol/L or less, and more preferably 0.5 mol/L or less. As the anticorrosive agent content decreases, the material cost of the polishing composition can be reduced, and additionally, the burden of treating the polishing composition after use in polishing, that is, the burden of waste liquid treatment can be reduced.

According to the present embodiment, the following advantages are obtained.

In the polishing composition of the present embodiment, the anticorrosive agent, which interacts with the group III-V compound material portion of the object to be polished, is used in order to suppress the occurrence of a level difference caused by etching on the surface of the object. Therefore, the polishing composition is suitably used for polishing the object including the group III-V compound material portion.

The embodiment described above may be modified as follows.
The polishing composition of the embodiment described above may contain two or more oxidizing agents.
The polishing composition of the embodiment described above may contain two or more anticorrosive agents. For example, an anticorrosive agent composed of a nitrogen-containing compound and an anticorrosive agent composed of an organic compound having a carboxyl group may be used in combination.
The polishing composition of the embodiment described above may further contain abrasive grains. The abrasive grains may be any of inorganic particles and organic particles. Specific examples of inorganic particles include particles made of a metal oxide, such as silica, alumina, ceria, and titania. Specific examples of organic particles include polymethyl methacrylate particles.
The polishing composition of the embodiment described above may further contain a known additive such as a preservative agent as required.
The polishing composition of the embodiment described above may be of a one-pack type or may be of a multi-pack type, such as a two-pack type.
The polishing composition of the embodiment described above may be prepared by diluting an undiluted solution of the polishing composition with water.

Next, examples of the present invention and comparative examples will be described.

Polishing compositions of Examples 1 to 7 were prepared by mixing an oxidizing agent and an anticorrosive agent with water. Polishing compositions of Comparative Examples 1 and 2 were prepared by mixing an oxidizing agent with water. The details of the components in each of the polishing compositions are shown in Table 1.

A gallium arsenide blanket wafer was cut into wafer small pieces each having four sides of 2 cm. Each wafer small piece was immersed in one of the polishing compositions of Examples 1 to 7 and Comparative Examples 1 and 2 at 25° C. for 5 minutes. The etching rate of gallium arsenide converted from the specific gravity (5.3 g/cm³) of gallium arsenide and the difference between the weights of the wafer small piece before and after immersion is shown in the column entitled “etching rate of GaAs” of Table 1.

TABLE 1

| | Oxidizing agent | | | Anticorrosive agent | | Etching rate |
|---|---|---|---|---|---|---|
| | | Standard electrode | Content | | Content | of GaAs |
| | Type | potential [V] | [mol/L] | Type | [mol/L] | [Å/min] |
| Example 1 | H₂O₂ | 1.7 | 0.2 | 1-H-1,2,4-triazole | 0.1 | 15 |
| Example 2 | H₂O₂ | 1.7 | 0.2 | Benzotriazole | 0.01 | 40 |
| Example 3 | H₂O₂ | 1.7 | 0.2 | Acetic acid | 0.1 | 55 |
| Example 4 | H₂O₂ | 1.7 | 0.2 | Citric acid | 0.1 | 48 |
| Example 5 | H₂O₂ | 1.7 | 0.2 | Succinic acid | 0.1 | 26 |
| Example 6 | Sodium dichloroisocyanurate | 1.6 | 0.2 | 1-H-1,2,4-triazole | 0.1 | 12 |
| Example 7 | Sodium dichloroisocyanurate | 1.6 | 0.2 | Succinic acid | 0.1 | 22 |
| Comparative | H₂O₂ | 1.7 | 0.2 | — | — | 163 |
| Example 1 | | | | | | |
| Comparative | Sodium dichloroisocyanurate | 1.6 | 0.2 | — | — | 135 |
| Example 2 | | | | | | |

As shown in Table 1, it was observed that in the case of Examples 1 to 7, in which the polishing composition contains an anticorrosive agent, the etching rate of gallium arsenide was decreased as compared with the case of Comparative Examples 1 and 2, in which the polishing composition contains no anticorrosive agents. This result suggests that an anticorrosive agent is effective for suppressing the occurrence of a level difference caused by etching.

1. A method for polishing, comprising:
providing an object including a portion containing a group III-V compound material; and
using a polishing composition to polish the object, wherein the polishing composition contains an oxidizing agent and an anticorrosive agent.

2. The method according to claim 1, wherein the oxidizing agent is dichloroisocyanuric acid or a salt thereof.

3. The method according to claim 2, wherein the oxidizing agent is a dichloroisocyanurate salt.

4. The method according to claim 3, wherein the oxidizing agent is sodium dichloroisocyanurate.

5. The method according to claim 1, wherein the oxidizing agent is contained in the polishing composition in an amount of 0.1 mol/L or more and 50 mol/L or less.

6. The method according to claim 1, wherein the anticorrosive agent is 1H-1,2,4-triazole.

7. The method according to claim 4, wherein the anticorrosive agent is 1H-1,2,4-triazole.

8. The method according to claim 1, wherein the anticorrosive agent is citric acid.

9. The method according to claim 4, wherein the anticorrosive agent is citric acid.

10. The method according to claim 1, wherein the anticorrosive agent is contained in the polishing composition in an amount of 0.01 mol/L or more and 0.5 mol/L or less.

11. A method for producing a substrate, comprising:
providing an object including a portion containing a group III-V compound material; and
using a polishing composition to produce a substrate by polishing the object, wherein the polishing composition contains an oxidizing agent and an anticorrosive agent.

12. The method according to claim 11, wherein the oxidizing agent is dichloroisocyanuric acid or a salt thereof.

13. The method according to claim 12, wherein the oxidizing agent is a dichloroisocyanurate salt.

14. The method according to claim 13, wherein the oxidizing agent is sodium dichloroisocyanurate.

15. The method according to claim 11, wherein the oxidizing agent is contained in the polishing composition in an amount of 0.1 mol/L or more and 50 mol/L or less.

16. The method according to claim 11, wherein the anticorrosive agent is a nitrogen-containing organic compound.

17. The method according to claim 16, wherein the anticorrosive agent is 1H-1,2,4-triazole.

18. The method according to claim 11, wherein the anticorrosive agent is an organic compound having a carboxyl group.

19. The method according to claim 18, wherein the anticorrosive agent is citric acid.

20. The method according to claim 15, wherein the anticorrosive agent is contained in the polishing composition in an amount of 0.01 mol/L or more and 0.5 mol/L or less.
